(19) United States
(12) Patent Application Publication
(10) Pub. No.: US 2006/0216615 A1
(43) Pub. Date: Sep. 28, 2006

(54) Wavefront engineering with off-focus mask features

(76) Inventors: Michael Goldstein, Ridgefield, CT (US); John M. Urata, Portland, OR (US)

Correspondence Address: FISH & RICHARDSON, PC, P.O. BOX 1022, MINNEAPOLIS, MN, 55440-1022, US

(21) Appl. No.: 11/093,001

(22) Filed: Mar. 28, 2005

(51) Int. Cl. G03C 5/00; G03B 27/42; G03F 1/00

(52) U.S. Cl. 430/5; 355/53; 430/322; 430/323; 430/324

(57) ABSTRACT

An imaging part such as a mask or reticle includes a patterned layer in an on-axis plane of the imaging part. The imaging part further includes another layer including sub-resolution features, where the another layer is positioned in an off-axis plane of the imaging part.

### BACKGROUND

A binary mask for use in optical lithography may include glass and chrome features which form a pattern. Light may pass through the clear glass areas and be blocked by the opaque chrome areas. Light passing through the mask may continue through a lens, which projects an image of the mask pattern onto a wafer. The wafer may be coated with a photosensitive film (photoresist), which undergoes a chemical reaction when exposed to light. After exposure, the areas on the photoresist exposed to the light may be removed in a developing process, leaving the unexposed areas as features on the wafer.

Typically, optical lithography uses unpolarized light to image the mask pattern on the wafer. However, some lithography applications may require polarized illumination. For example, immersion lithography is a resolution-enhancement technique that utilizes polarized light. In immersion lithography, a liquid medium may be interposed between the optics and the wafer surface, replacing the usual air gap. For 193 nm exposure wavelength, the typical liquid used is ultra-pure, degassed water. Immersion lithography may increase the effective depth-of-focus for a given numerical aperture and permits the use of optics with numerical apertures above 1.0, thus raising the maximum resolution potential of 193 nm technology.

### BRIEF DESCRIPTION OF THE DRAWINGS

FIG. 1A is a sectional view of a mask according to some implementations.

FIG. 1B is a sectional view of a mask according to other implementations.

FIGS. 2A-2F show a process flow for fabricating the mask shown in FIG. 1A.

FIGS. 3A-3D show various types of polarizing features in the mask.

FIG. 4 is a plot showing image contrast through pitch of equal line/space patterns for a polarizing mask and a non-polarizing mask.

FIG. 5 shows a mask including off-focus sub resolution assist features.

FIG. 6 shows a mask including off-focus sub resolution assist features positioned directly over a feature in a patterned layer of the mask.

FIGS. 7A-7E show a process flow for fabricating a mask with off-focus sub resolution assist features.

Like reference symbols in the various drawings indicate like elements.

### DETAILED DESCRIPTION

Changing the polarization state of imaging light is one way of modifying imaging light. As noted above, polarization of imaging light is used in immersion lithography.

Systems and techniques provided herein allow for modifying illumination and/or diffraction wavefronts at a mask in a lithography tool. The wavefronts may be modified using off-focus mask features. Note that, although the term “mask” is predominantly used herein, this terminology is for descriptive purposes. The systems and techniques may also be used with other imaging parts such as reticles.

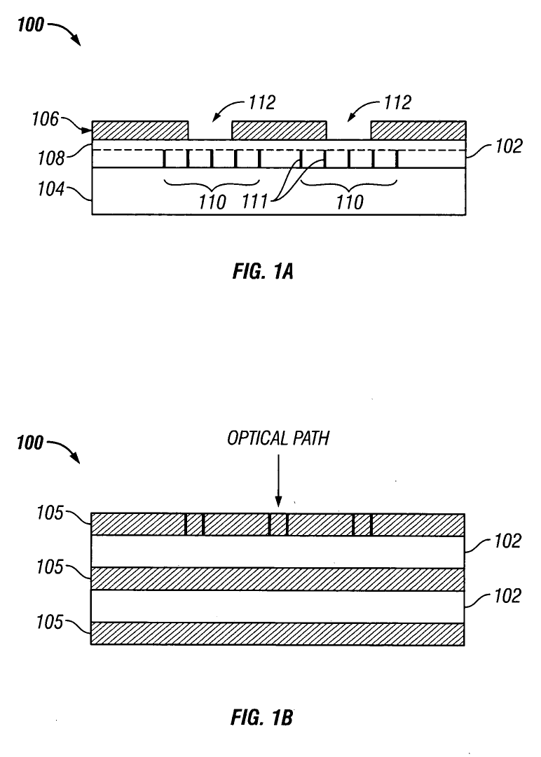

FIG. 1 shows a sectional view of an implementation of a mask 100 incorporating features 111 in an off-focus layer 102 of mask 100. In some implementations, layer 102 is a polarizing layer on a mask substrate 104. Mask substrate 104 may be formed from a material that is transmissive (e.g., substantially transmissive) to light of the exposure wavelength. For example, mask substrate 104 may be an appropriate glass.

Mask 100 further includes a patterned layer 106 including features 112 for transferring a pattern to a substrate in an imaging plane. Patterned layer 106 is said to be an “on-focus” layer of mask 100, since features 112 are in focus at the imaging plane (e.g., a plane formed by a photoresist layer on the wafer substrate during a lithography process).

Polarizing layer 102 may be separated from a patterned layer 106 by an intervening absentee layer 108. Providing polarizing features on the mask may provide a number of benefits. For example, for an immersion lithography system, a polarized illuminator or other polarizer in the optical path between the illumination source and wafer may not be required. This may reduce the complexity and cost of the lithography system.

In some implementations, features 111 may be arranged as one or more polarizers 110, which may be grating polarizers. Features 111 may be sub-resolution features; that is, they may be a size that is too small to be resolved at the imaging plane for a particular exposure wavelength. The features may thus not print when exposed at the exposure wavelength. However, they may change the diffraction pattern of light to locally change the polarization of light passing through the polarizing layer 102.

The grating polarizers 110 may be positioned to modify light transmitted through corresponding features (e.g., spaces) 112 in the patterned layer 106. The polarizing features may substantially or fully polarize light transmitted through features 112, which is subsequently incident on the substrate.

Like the mask substrate material, the absentee layer material may be transmissive (e.g., substantially transmissive) to light of the exposure wavelength. Locally polarized light from the polarizing layer 102 may pass through the absentee layer 108 and the exposed regions 112 in the patterned layer 106 onto the imaging plane at the wafer.

FIG. 1B shows a sectional view of another implementation of a mask 100. Mask 100 includes two or more featured layers 105. Featured layers 105 may be separated by substantially transmissive layers 102. One of featured layers 105 is an on-axis layer including features to be printed on a substrate such as a wafer. At least one of featured layers 105 is an off-axis layer for modifying imaging light using polarization features and/or features such as sub-resolution assist features. Note that mask 100 generally includes a mask substrate layer.

In an example, one of featured layers 105 may be an on-axis patterning layer. A different one of featured layers 105 may be an off-axis polarization layer, and may have polarization features positioned with respect to corresponding ones of the features of the on-axis patterning layer. A different one of featured layers 105 may be an off-axis assist layer, incorporating sub-resolution assist features positioned with respect to corresponding ones of the features of the on-axis patterning layer.

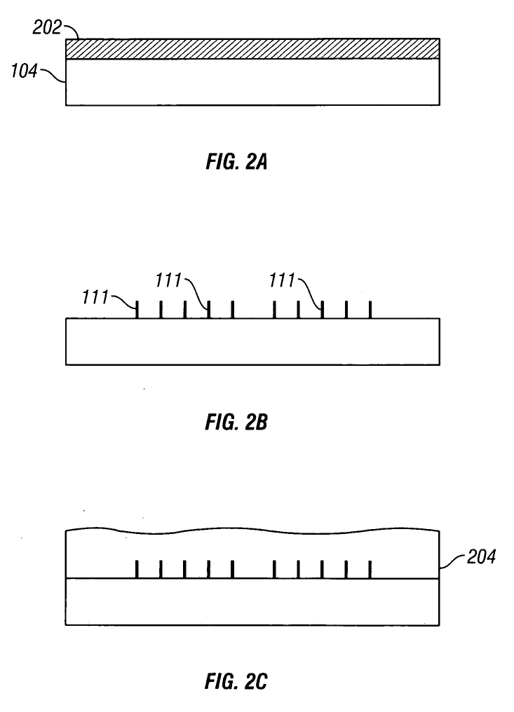

FIGS. 2A-2F show an exemplary process flow for fabricating a mask 100 incorporating polarization features arranged as polarizers 110. The polarizing layer may be formed by depositing a layer of opaque material 202, such as chrome, on a glass substrate 104, as shown in FIG. 2A. The chrome may be selectively etched to form the polarizing features 111 using photolithography techniques, as shown in FIG. 2B.

An absentee layer material 204 may be deposited, as shown in FIG. 2C. The absentee layer may act as a spacer between the polarizing features in the polarizing layer and imaging features in the patterned layer. The absentee layer may then be optically polished to form an absentee layer 108 with a substantially smooth, flat surface 206 and a desired thickness, as shown in FIG. 2D.

The absentee layer may be formed from any suitable material for spacing between the polarizing layer and imaging features. For example, they may be a material with a low glass transition temperature (Tg), e.g., low-Tg silicon dioxide. The absentee layer material may be a material which may be deposited conformally, a material which may form a substantially flat surface as deposited, and/or which may be polished to form a smooth, flat surface. Some examples of suitable absentee layer materials include, for example, a spin-on polymer or a sol-gel glass.

The patterned layer may then be formed by depositing another layer of an opaque material 208, e.g., chrome, on the smooth surface of the absentee layer, as shown in FIG. 2E. The chrome may be selectively etched to form the features 112 to be printed using photolithography techniques, as shown in FIG. 2F.

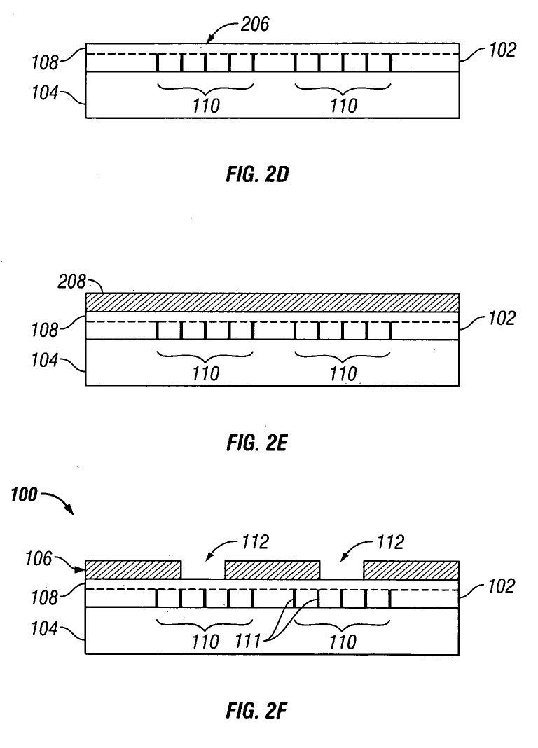

The polarizing features in the polarizing layer may have a variety of different shapes and/or orientations. A polarizing feature may have a shape and orientation which match a corresponding imaging feature in the patterned layer. FIGS. 3A-3D show some examples of polarizing features. FIGS. 3A and 3B show polarizing features 302 and 304 which may be used to linearly polarize light. Polarizing feature 302 may polarize light in one direction, and polarizing feature 304 may polarize light in an orthogonal direction. Polarizing features 302 and 304 may be used for, e.g., rectangular features.

FIGS. 3C and 3D show polarizing features 310, 312 which may be used to circularly polarize light. Polarizing feature 310 has a spoke pattern, and polarizing feature 312 has concentric circular features. The polarizing features 310 and 312 may be used for circular features, such as vias. Note that other types of polarization features may be used as well; for example, features to elliptically polarize light.

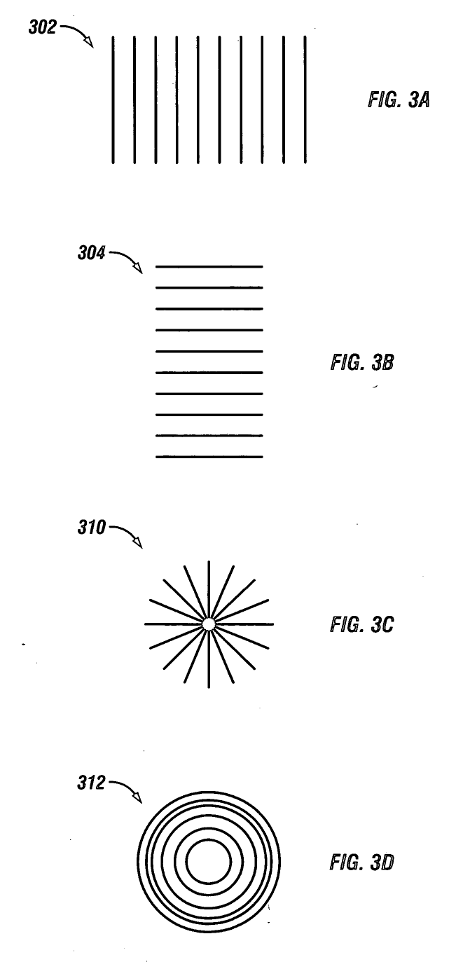

FIG. 4 is a plot showing theoretical image contrast 402, 404 as a function of pitch for equal line/space patterns using a polarizing mask (with a polarizing layer) and an non-polarizing (conventional) mask, respectively. The results were generated from a modeled lithography system with a 0.93 numerical aperture (NA), 193 nm exposure wavelength, and 0.8 conventional partial coherence.

As shown in the plot, near the resolution limit the polarizing mask provides about 50% greater image contrast than the non-polarizing mask. Of course, other results may also be obtained, and are intended to be encompassed within this disclosure.

In some implementations, an absentee layer may also be used in masks to form spaces, allowing sub resolution assist features to be out of focus. Sub resolution assist features may be additional small features, typically added to the mask using simple width and spacing rules. These features typically do not themselves print on the wafer, but may enable isolated or semi-isolated lines to diffract light like dense lines.

In conventional transmissive masks, sub resolution assist features may be provided in the patterned layer along with the features to be imaged on the photoresist (i.e., in an on-focus layer of the mask). This contrasts with the above-disclosed implementation, in which the sub resolution assist features are separated from features in the (on-focus) patterned layer; for example, by the absentee layer. Positioning at least some sub resolution assist features in an off-axis mask layer may add another degree of freedom in providing sub resolution assist features. This may in turn enable new mask designs.

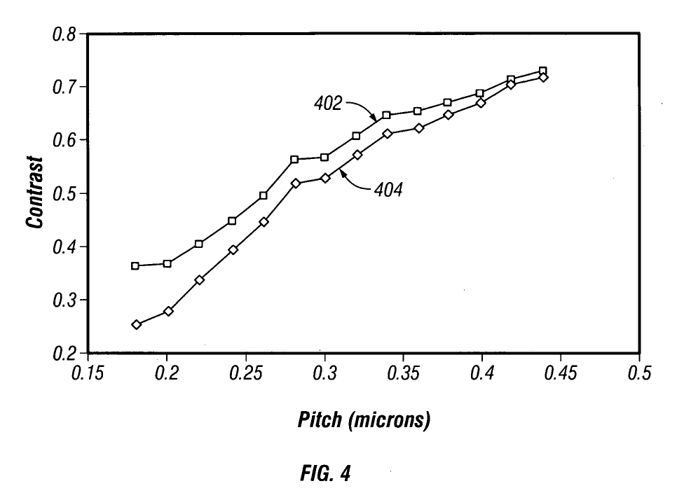

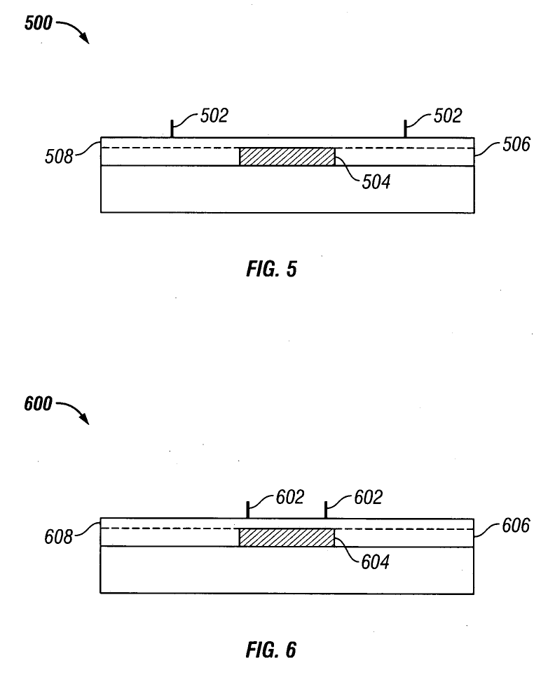

FIG. 5 shows a mask 500 with out-of-focus sub resolution assist features 502, e.g., scattering bars, separated from a feature 504 in a patterned layer 506 by an absentee layer 508. In this case, the out-of-focus sub resolution assist features 502 are provided at the periphery of the feature 504 in the patterned layer 506. In an alternative embodiment, sub resolution assist features 602 may be provided directly over a feature 604 in a patterned layer 606, as shown in FIG. 6. This arrangement is different than a conventional mask. This takes advantage of the additional degree of freedom provided by the absentee layer 608.

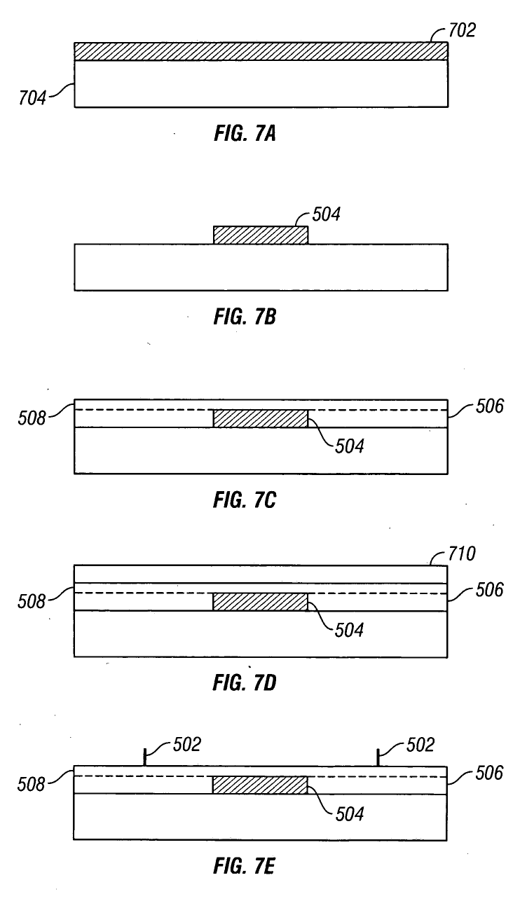

FIGS. 7A-7F show an exemplary process flow for fabricating the mask 500 shown in FIG. 5. In this implementation, the patterned layer may be formed first. A layer of opaque material 702, such as chrome, may be deposited on a glass substrate 704, as shown in FIG. 7A. The chrome may be selectively etched to form the features to be printed (e.g., feature 504) using photolithography techniques, as shown in FIG. 7B.

The absentee layer 508 may then be deposited and optically polished, as shown in FIG. 7C. Another opaque layer 710 may be deposited on the polished surface of the absentee layer 508, as shown in FIG. 7D. The chrome may be selectively etched to form out-of-focus sub resolution features 502, as shown in FIG. 7E.

A number of implementations have been described. Although only a few implementations have been disclosed in detail above, other modifications are possible, and this disclosure is intended to cover all such modifications, and most particularly, any modification which might be predictable to a person having ordinary skill in the art. For example, blocks in the process flows may be skipped or performed out of order and still produce desirable results. In another example, the absentee layer may be omitted in some implementations, and the on-axis and off-axis features may be patterned in successive opaque (e.g., chrome) layers.

Also, only those claims which use the words “means for” are intended to be interpreted under 35 USC 112, sixth paragraph. Moreover, no limitations from the specification are intended to be read into any claims, unless those limitations are expressly included in the claims. Accordingly, other embodiments are within the scope of the following claims.

What is claimed is:

1. An imaging part comprising:
a patterned layer including a plurality of features of a size which can be printed, the patterned layer positioned in an on-axis plane of the imaging part; and
another layer, the another layer including a plurality of sub resolution features and positioned in an off-axis plane of the imaging part.

2. The imaging part of claim 1, further comprising an absentee layer separating the patterned layer and the another layer.

3. The imaging part of claim 1, wherein the imaging part is one of a mask or a reticle, and wherein at least one of the patterned layer and the another layer are formed on an imaging part substrate.

4. The imaging part of claim 1, wherein the plurality of sub resolution features are operative to change a diffractive property of radiation at an exposure wavelength passing through the imaging part.

5. The imaging part of claim 1, wherein the sub resolution features are operative to polarize radiation at the exposure wavelength.

6. The imaging part of claim 5, wherein the plurality of said sub resolution features are included in at least one polarizer.

7. The imaging part of claim 6, wherein the polarizer is operative to linearly polarize radiation at the exposure wavelength.

8. The imaging part of claim 7, wherein the polarizer includes a plurality of linear sub resolution features.

9. The imaging part of claim 6, wherein the polarizer is operative to circularly polarize radiation at the exposure wavelength.

10. The imaging part of claim 6, wherein the polarizer is operative to elliptically polarize radiation at the exposure wavelength.

11. The imaging part of claim 1, wherein the plurality of sub resolution features comprise a sub resolution assist feature having a position corresponding to a position of a feature in the patterned layer.

12. The imaging part of claim 11, wherein the sub resolution assist feature has a position corresponding to a periphery of the position of said feature in the patterned layer.

13. The imaging part of claim 11, wherein the sub resolution assist feature has a position directly over said feature in the patterned layer.

14. A method comprising:
forming a first layer on an imaging part substrate;
patterning the first layer;
forming a second layer proximate to the first layer; and
patterning the second layer;
wherein one of the first layer and the second layer is an on-axis layer including features to be printed on a device substrate, and wherein the other of the first layer and the second layer is an off-axis layer including sub-resolution features positioned relative to a corresponding feature to be printed on a device substrate.

15. The method of claim 14, further comprising forming an intervening layer on the first layer, wherein the intervening layer is transmissive of light of an imaging wavelength, and wherein forming the second layer proximate to the first layer comprises forming the second layer on the intervening layer.

16. The method of claim 14, wherein the first layer is the off-axis layer and the second layer is the on-axis layer, and wherein forming the first layer comprises depositing an opaque material on the imaging part substrate;
wherein patterning the first layer comprises forming a plurality of sub-resolution polarizing features;
wherein forming the second layer comprises depositing a second layer of opaque material on one of an intervening layer and the first layer; and
wherein patterning the second layer comprises forming a plurality of features to be printed.

17. The method of claim 14, wherein the first layer is the on-axis layer and the second layer is the off-axis layer, and wherein forming the first layer comprises depositing an opaque material on the imaging part substrate;
wherein patterning the first layer comprises forming a plurality of features to be patterned on a substrate;
wherein forming the second layer comprises depositing a second layer of opaque material on one of an intervening layer and the first layer; and
wherein patterning the second layer comprises forming a plurality of sub-resolution assist features.

18. A system comprising:
an imaging part, the imaging part including:
a patterned layer including a plurality of features of a size which can be printed, the patterned layer positioned in an on-axis plane of the imaging part; and
another layer, the another layer including a plurality of sub resolution features and positioned in an off-axis plane of the imaging part; and
a light source positioned to transmit light through the imaging part.

19. The system of claim 18, wherein the system is an immersion lithography system, and wherein the plurality of sub-resolution features include polarization features.

20. The system of claim 18, wherein the imaging part is one of a mask and a reticle.
